(19) United States
(12) Patent Application Publication
(10) Pub. No.: US 2023/0187333 A1
(43) Pub. Date: Jun. 15, 2023

(54) SUBSTRATE STRUCTURE AND ELECTRONIC DEVICE

(71) Applicant: PanelSemi Corporation, New Taipei City (TW)

(72) Inventors: CHIA-CHIN TU, New Taipei City (TW); HSIEN-TE CHEN, Taipei City (TW)

(21) Appl. No.: 18/079,261

(22) Filed: Dec. 12, 2022

Related U.S. Application Data
(60) Provisional application No. 63/313,511, filed on Feb. 24, 2022.
(60) Provisional application No. 63/288,838, filed on Dec. 13, 2021.

(51) Int. Cl. H01L 23/498

(52) U.S. Cl. CPC H01L 23/49827

(57) ABSTRACT

A substrate structure includes a substrate and plural conductive structures. The substrate has a substrate body, plural through holes penetrating the substrate body, and two conductive patterns formed on two opposite surfaces of the substrate body respectively. The substrate body is defined with two openings, a hole wall, and a surface roughness along the hole wall. The conductive structures are respectively oriented at the through holes. Each conductive structure is defined with two larger-diameter caps, and a small-diameter segment linking the two larger-diameter caps. In each conductive structure, the two larger-diameter caps are respectively located at the two openings and electrically connected the two conductive patterns, and the surface roughness of the small-diameter segment is less than the surface roughness of the hole wall of a corresponding one of the through holes.

### CROSS REFERENCE TO RELATED APPLICATIONS

The non-provisional patent application claims priority to U.S. Provisional Pat. Applications with Serial No. 63/288,838 filed on Dec. 13, 2021 and Serial No. 63/313,511 filed on Feb. 24, 2022. This and all other extrinsic materials discussed herein are incorporated by reference in their entirety.

### BACKGROUND

### Technology Field

The disclosure relates to a substrate structure, a method for fabricating the substrate structure, and an electronic device with the substrate structure.

### Description of Related Art

Regarding the manufacturing process of electronic devices, especially photoelectric devices, in order to electrically connect the circuit layer formed on the upper surface of the substrate and the circuit layer formed on the lower surface of the substrate, the conventional method is to drill holes through the substrate first, and then to form a conductive film in the hole by chemical plating or/and electroplating process. Accordingly, the conductive film formed in the holes can connect to the circuit layers formed on the upper and lower surfaces respectively, thereby achieving the purpose of electrically connecting the circuit layers on the upper and lower surfaces of the substrate.

However, the manufacturing method of utilizing chemical plating or electroplating process to form the conductive film will cause the non-smooth structure of the conductive film or/and the hole wall of the through hole. When transmitting the high-frequency signals via the conductive film in the through holes, it can easily cause the signal attenuation, thereby resulting in the poor signal transmission.

### SUMMARY

This disclosure provides a novel substrate structure and an electronic device with the substrate structure, which can improve the signal attenuation of high-frequency signals.

The substrate structure of this disclosure can be applied to, for example but not limited to, the antenna unit technology field.

One or more exemplary embodiments of this disclosure provide a substrate structure, including a substrate and a plural of conductive structures accommodated within the substrate. The substrate has a substrate body, a plural of through holes penetrating the substrate body, and two conductive patterns; the substrate body is defined with two surfaces opposite to each other, the two conductive patterns are formed on the two surfaces of the substrate body respectively; the substrate body is, in accordance with each of the through holes, defined with two openings, a hole wall, and a surface roughness along the hole wall. The conductive structures are respectively oriented at the through holes of the substrate, wherein each of the conductive structures is defined with two larger-diameter caps, and a small-diameter segment linking the two larger-diameter caps. In each of the conductive structures, the two larger-diameter caps are respectively located at the two openings and electrically connected the two conductive patterns, the small-diameter segment is defined with a surface roughness, the surface roughness of the small-diameter segment is less than the surface roughness of the hole wall of a corresponding one of the through holes.

In one exemplary embodiment, the substrate is a resilient board.

In one exemplary embodiment, the substrate is a rigid board.

In one exemplary embodiment, the substrate includes a rigid board, a resilient board, and an adhesion layer connecting the rigid board and the resilient board.

In one exemplary embodiment, the resilient board and the adhesion layer further define a combined thickness less than or equal to 60 µm.

In one exemplary embodiment, in each of the conductive structures, one of the two larger-diameter caps and the small-diameter segment are formed to be a conductive pin as integrity.

In one exemplary embodiment, the small-diameter segment includes metallic materials including gold, silver, tin, copper, aluminum, iron, nickel, or cobalt, or an alloy including at least one of the foresaid metallic materials.

In one exemplary embodiment, a part of the small-diameter segment directly contacts the hole wall.

In one exemplary embodiment, the substrate body is defined with a thickness, and the thickness is less than or equal to 1.1 mm.

In one exemplary embodiment, the substrate body is defined with a thickness, and the thickness is greater than or equal to 0.5 mm.

In one exemplary embodiment, the substrate body is defined with a thickness, and the thickness is greater than or equal to 0.4 mm.

In one exemplary embodiment, the substrate body is defined with a thickness, and the thickness is greater than or equal to 0.01 mm.

In one exemplary embodiment, each of the through holes is defined with a diameter, and the diameter of the through hole is less than or equal to 100 µm.

In one exemplary embodiment, each of the through holes is defined with a diameter, and the diameter of the through hole is less than or equal to 80 µm.

In one exemplary embodiment, each of the through holes is defined with a diameter, and the diameter of the through hole is less than or equal to 75 µm.

In one exemplary embodiment, each of the through holes is defined with a diameter, and the diameter of the through hole is greater than or equal to 35 µm.

In one exemplary embodiment, the small-diameter segment of the each of the conductive structures is defined with a diameter, and the diameter of the small-diameter segment is less than or equal to 50 µm.

In one exemplary embodiment, the small-diameter segment is defined with a diameter, and the diameter of the small-diameter segment is less than or equal to 25 µm.

In one exemplary embodiment, each of the through holes is defined with a depth-to-diameter aspect ratio, and the depth-to-diameter aspect ratio is less than or equal to 50.

In one exemplary embodiment, one of the larger-diameter caps of one of the conductive structures is defined with a diameter, which is greater than a corresponding one of openings of the through holes.

In one exemplary embodiment, the substrate structure further includes a conductive circle encompassing along the hole wall of a corresponding one of the through holes; and an insulation sleeve sheathing the small-diameter segment and arranged between the small-diameter segment of the corresponding conductive structure and the hole wall of a corresponding one of the through holes.

In one exemplary embodiment, one of the conductive patterns includes a conductive pad, and a corresponding one of the conductive structures electrically connects the conductive pads.

One or more exemplary embodiments of this disclosure provide an electronic device, comprising the above-mentioned substrate structure and a plural of electrical components distributed on one of the surfaces of the substrate body, electrically connected one of the conductive patterns in a respective manner to the other one of the conductive patterns through the conductive structures.

One or more exemplary embodiments of this disclosure provide a method for fabricating a substrate structure, comprising: preparing a substrate, in which the substrate includes a substrate body, a plural of through holes penetrating the substrate body, and two conductive patterns formed on two opposite surfaces of the substrate body; the substrate body is defined with two openings, a hole wall, and a surface roughness along the hole wall in accordance with each of the through holes; orientating a plural of conductive pins to the through holes; wherein each of the conductive pins is defined with a first larger-diameter cap and a small-diameter segment linking the first larger-diameter cap, the first larger-diameter cap locates at a corresponding one of the two openings; the small-diameter segment is defined with a surface roughness, the surface roughness of the small-diameter segment is less than the surface roughness of the hole wall of a corresponding one of the through holes; and electrically connecting the first larger-diameter cap with a corresponding one of the two conductive patterns.

In one exemplary embodiment, the method for fabricating a substrate structure further includes: laser welding one end of the small-diameter segment away from the large-diameter cap to form a second larger-diameter cap to electrically connect the other one of the two conductive patterns.

In one exemplary embodiment, the method for fabricating a substrate structure further includes: disposing a conductive material at one end of the small-diameter segment, and heating the conductive material to form a second larger-diameter cap to electrically connect the other one of the two conductive patterns.

In one exemplary embodiment, the conductive material includes gold, silver or tin materials.

In one exemplary embodiment, in the step of the electrically connecting the first larger-diameter cap, the method for fabricating a substrate structure further includes: laser welding the first larger-diameter cap with the corresponding one of the two conductive patterns.

One or more exemplary embodiments of this disclosure provide a method for fabricating a substrate structure, comprising: preparing a substrate, wherein the substrate includes a substrate body, a plural of through holes penetrating the substrate body, and two conductive patterns formed on two opposite surfaces of the substrate body, and the substrate body is defined with two openings, a hole wall, and a surface roughness along the hole wall in accordance with each of the through holes; orientating a plural of conductive pins to the through holes, wherein each of the conductive pins is defined with a small-diameter segment, an end of the small-diameter segment locates at a corresponding one of the two openings, the small-diameter segment is defined with a surface roughness, and the surface roughness of the small-diameter segment is less than the surface roughness of the hole wall of a corresponding one of the through holes; and forming the end of the small-diameter segment as a first larger-diameter cap for electrically connecting with a corresponding one of the two conductive patterns.

In one exemplary embodiment, the method further includes: laser welding a distal end of the small-diameter segment as a second larger-diameter cap to electrically connect the other one of the two conductive patterns.

In one exemplary embodiment, the method further includes: disposing a distal end of the small-diameter segment with a conductive material, and heating the conductive material as a second larger-diameter cap to electrically connect the other one of the two conductive patterns.

In one exemplary embodiment, the conductive material includes gold, silver or tin materials.

In one exemplary embodiment, in the step of electrically connecting the first larger-diameter cap, further includes: laser welding the end of the small-diameter segment as the first larger-diameter cap and bonding with the corresponding one of the two conductive patterns.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1A is a schematic diagram showing an electronic device including a substrate structure according to an embodiment of this disclosure;

FIG. 1B is an enlarged view of a part of the electronic device of FIG. 1A;

FIGS. 2A to 2C are schematic enlarged views of a part of different substrate structures according to different embodiments of this disclosure;

FIG. 3 is a flow chart of a method for fabricating a substrate structure; and

FIG. 4 is a schematic view showing a conductive pin according to an embodiment of this disclosure.

### DETAILED DESCRIPTION OF THE DISCLOSURE

The present disclosure will be apparent from the following detailed description, which proceeds with reference to the accompanying drawings, wherein the same references relate to the same elements.

Advantages and features of the present invention and methods for achieving them will be made clear from embodiments described below in detail with reference to the accompanying drawings. The present invention may, however, be embodied in many different forms and should not be construed as being limited to the embodiments set forth herein. Rather, these embodiments are provided so that this disclosure will be thorough and complete, and will fully convey the scope of the invention to those skilled in the art. The present invention is merely defined by the scope of the claims. Therefore, well-known constituent elements, operations and techniques are not described in detail in the embodiments in order to prevent the present invention from being obscurely interpreted. Like reference numerals refer to like elements throughout the specification.

The spatially relative terms “below”, “beneath”, “lower”, “above”, “upper”, and the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device shown in the drawing is turned over, the device positioned “below” or “beneath” another device may be placed “above” another device. Accordingly, the illustrative term “below” may include both the lower and upper positions. The device may also be oriented in the other direction, and thus the spatially relative terms may be interpreted differently depending on the orientations.

Throughout the specification, when an element is referred to as being “connected” to another element, the element is “directly connected” to the other element, or “electrically connected” to the other element with one or more intervening elements interposed therebetween. It will be further understood that the terms “comprises”, “comprising”, “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms used herein (including technical and scientific terms) have the same meaning as commonly understood by those skilled in the art to which this invention pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the present specification.

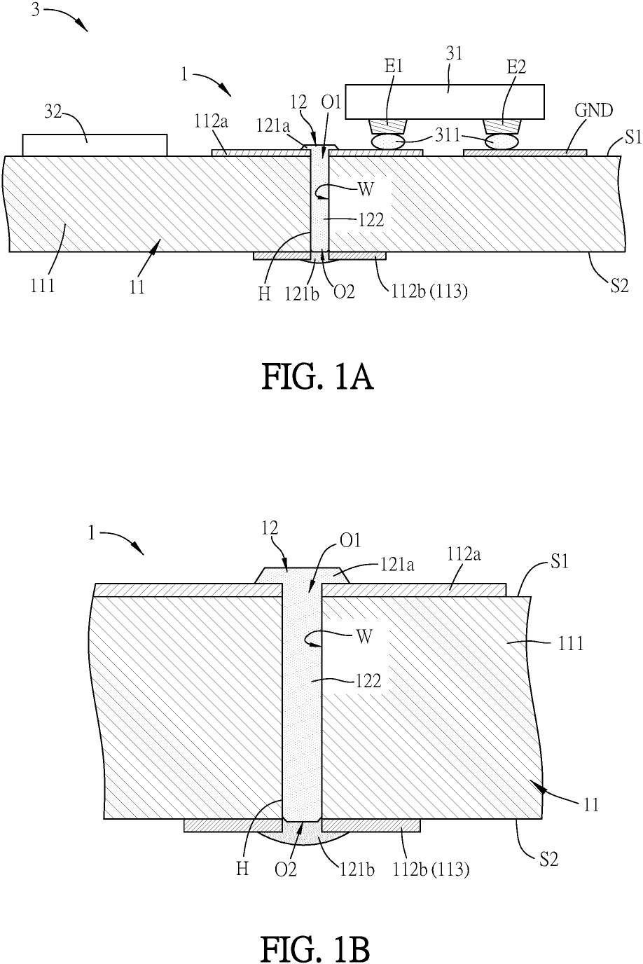

FIG. 1A is a schematic diagram showing an electronic device according to an embodiment of this disclosure, and FIG. 1B is an enlarged view of a part of the electronic device of FIG. 1A.

Referring to FIGS. 1A and 1B, an electronic device 3 includes a substrate structure 1 and a plurality of electronic components 31. The electronic components 31 are distributed on a surface of the substrate structure 1. FIG. 1A shows, for example, one electronic component 31 distributed on the surface of the substrate structure 1. In some embodiments, the plurality of electronic components 31 can be distributed on the substrate structure 1 in a one-dimensional or two-dimensional array, but this disclosure is not limited thereto. In other embodiments, the plurality of electronic components 31 can be distributed on the substrate structure 1 in a circle, an ellipse, in a n*m matrix, or any of other shapes.

The substrate structure 1 includes a substrate 11 and a plurality of conductive structures 12. The substrate 11 includes a substrate body 111, a plurality of through holes H, and two conductive patterns 112a and 112b. The substrate body 111 is defined with two surfaces S1 and S2 opposite to each other (i.e., the upper surface and the lower surface), and the two conductive patterns 112a and 112b are formed on the two surfaces S1 and S2, respectively. Each through hole H penetrates through the substrate body 111, communicates the surfaces S1 and S2 of the substrate body 111, and is adjacent to the conductive patterns 112a and 112b. In addition, the substrate body 111, corresponding to each through hole H, is defined with two openings O1 and O2 and a hole wall W, in order to constitute each of the through holes H.

The substrate 11 can be a rigid substrate, a resilient substrate, or any combination thereof. In another case, the substrate 11 can include a rigid board, a resilient board, and an adhesion layer for connecting the rigid board and the resilient board, wherein the combined thickness of the resilient board and the adhesion layer can be less than or equal to 60 µm. For example, the thickness of the resilient board can be 15 µm, and the thickness of the adhesion layer can be 35 µm so as to cover a layout arranged on the resilient board. To be understood, when the thickness of the resilient board increases, the physical properties thereof can approach that of the rigid board. The substrate body 111 can be a rigid substrate, a resilient substrate, or a combination of at least one rigid substrate and at least one resilient substrate. The resilient substrate can include PI (Polyimide) material, adhesion layer, or a combination thereof. In this embodiment, for example, the substrate body 111 is a rigid substrate, which is made of glass or Polytetrafluoroethylene (PTFE) material.

The substrate body 111 can define a thickness, which can be, for example but not limited to, less than or equal to 1.1 mm, and greater than or equal to 0.01 mm. For example, the thickness of the substrate body 111 can be 1.1 mm, 0.5 mm, 0.4 mm, 0.3 mm, or 0.01 mm. The substrate body 111 usually has a uniform thickness, but this disclosure is not limited thereto. When the substrate body 111 has a non-uniform thickness, the defined thickness can be the minimum thickness of the entire substrate body 111. In addition, the conductive patterns 112a and 112b can be used to transmit electrical signals. The material of the conductive patterns 112a and 112b can include, for example, metals (i.e., gold, silver, copper, aluminum, iron, nickel, cobalt or tin), or any combination of the metals, or an alloy of any of their combinations, or any of other conductive materials. The conductive patterns 112a and 112b may be formed as pads extending from circuits, or parts of the traces of circuits, or a metallic plane per se; for example, the metallic plane could be designed as an antenna pattern, which includes a plural of antenna units. That is, one antenna unit corresponds to one conductive structure 12. In this embodiment, each antenna unit is a planar antenna unit. Each antenna unit could connect to or extend from the conductive pattern 112b. Accordingly, the electric signals can be transmitted by the electronic component 31 with the antenna unit through the conductive pattern 112a, the conductive structure 12 and the conductive pattern 112b.

In some embodiments, the sizes of the opening O1 and the opening O2 can be the same or different. In addition, each through hole H is defined with a diameter, which can be the minimum diameter of the through hole H such as, for example but not limited to, less than or equal to 70 µm. In addition, the diameter of the through hole H, which can be the maximum diameter of the through hole H such as, for example but not limited to, can be greater than or equal to 35 µm. There are still optional and possible dimensions of the diameter of the through hole H, for example, the diameter of the through hole H is 100 µm, 80 µm, 75 µm, 50 µm, 35 µm, 25 µm, 15 µm, or 10 µm. Herein, the through hole H can have a uniform diameter (i.e., the through hole H has one diameter value); or the diameter of the through hole H is not uniform (i.e., the through hole H has a narrower middle portion and wider top and bottom portions, or the through hole H is gradually wider from bottom to top or from top to bottom). In addition, each through hole H can be further defined with a depth-to-diameter aspect ratio (the ratio of the depth of the through hole H to the diameter of the through hole H). The depth-to-diameter aspect ratio of each through hole H can be less than or equal to 50 or/and greater than or equal to 3. In some cases, the depth-to-diameter aspect ratio of each through hole H can be greater than or equal to 4. In some cases, the depth-to-diameter aspect ratio of each through hole H can be greater than or equal to 5. The depth of each through hole H can be realized as the thickness of the substrate body 111. For example, when the substrate body 111 has a uniform thickness, the depths of all through holes H are equal to the thickness of the substrate body 111. Otherwise, when the substrate body 111 does not have a uniform thickness, the depths of all through holes H are different values. In some embodiments, the through holes H can be formed by, for example, laser drilling.

A plurality of conductive structures 12 are placed in the through holes H of the substrate 11, respectively. FIGS. 1A and 1B show that one conductive structure 12 penetrates through the substrate body 111, and is placed in the through hole H of the substrate 11. Each conductive structure 12 is defined with two larger-diameter caps 121a and 121b at opposite ends of the conductive structure 12, and a small-diameter segment 122 linking the two larger-diameter caps 121a and 121b. That is, two opposite ends of the small-diameter segment 122 connect the larger-diameter cap 121a and the larger-diameter cap 121b, respectively. Herein, at least a part of the small-diameter segment 122 of each conductive structure 12 directly contacts the hole wall W. In some embodiments, the material of the larger-diameter caps 121a and 121b can be the same as or different from the material of the small-diameter segment 122, and the material of the larger-diameter cap 121a can be the same as or different from the material of the larger-diameter cap 121b. This disclosure is not limited thereto. In this embodiment, the material of the larger-diameter cap 121a is the same as that of the small-diameter segment 122, but the material of the larger-diameter cap 121a is different from that of the larger-diameter cap 121b. In this embodiment, the larger-diameter cap 121a and the small-diameter segment 122 are formed to be a conductive pin as integrity, but the larger-diameter cap 121b and the small-diameter segment 122 are not. Herein, the larger-diameter cap 121b is formed at one end of the small-diameter segment 122 by an additional process. The material of the larger-diameter cap 121b can be, for example but not limited to, a metal material (i.e., gold, silver , copper, aluminum, iron, nickel, cobalt or tin), and the material of the small-diameter segment 122 can be a magnetic conductive material or/and a thermoelectric material such as, for example but not limited to, a metal material (i.e., gold, silver, tin, copper, aluminum, iron, nickel, and cobalt), or an alloy formed by at least one of the foregoing materials. This disclosure is not limited thereto.

In some embodiments, the small-diameter segment 122 of the conductive structure 12 is defined with a diameter, which can be smaller than or equal to 50 µm or smaller than or equal to 25 µm. For example, the diameter of the small-diameter segment 122 can be 50 µm, 25 µm, 17 µm, 15 µm, 5 µm, or the likes. In some embodiments, each of the larger-diameter caps 121a and 121b of one conductive structure 12 can be defined with a diameter, which is larger than the diameter of the corresponding opening O1 or O2 of the corresponding through hole H. The above-mentioned diameters can be the largest value defined on the plane parallel to the surface S1 or S2 of the substrate body 111. In some embodiments, one of the conductive structure 12 is positioned in the corresponding through hole H, the opening O1 of the through hole H is larger than the other opening O2 of the through hole H, and the outer surface (upper surface) of the larger-diameter cap 121a of the conductive structure 12 is coplanar with the surface S2 of the substrate body 111. That is, the conductive structure 12 is a countersunk head conductive structure.

The larger-diameter caps 121a and 121b of each conductive structure 12 are respectively located at the openings O1 and O2 of the corresponding through hole H, and are electrically connected to the conductive patterns 112a and 112b, respectively. Accordingly, the conductive pattern 112a can electrically connect the conductive pattern 112b via the conductive structure 12 located in the through hole H, so that the signals can be transmitted from the conductive pattern 112a to the conductive pattern 112b through the conductive structure 12 in the through hole H, and vice versa. In addition, the conductive pattern 112b can further include a conductive pad 113, and one of the conductive structures 12 is electrically connected to the conductive pad 113.

In this embodiment, the surface roughness of the small-diameter segment 122 of each conductive structure 12 is less than the surface roughness of the hole wall W of the corresponding through hole H. In the high-frequency range, the surface of the conductive structure 12 performs well with reduced transmission loss due to its low roughness.

Referring to FIG. 1A, a plurality of electronic components 31 are distributed on one surface of the substrate body 111 and electrically connected to the corresponding conductive pattern 112a, and the electronic components 31 are electrically connected to another conductive pattern 112b through the conductive structures 12. Accordingly, the electrical signal outputted from the electronic component 31 can be transmitted from the conductive pattern 112a to the conductive pattern 112b through the conductive structure 12. Specifically, a signal end E1 of the electronic component 31 is electrically connected to the conductive pattern 112a of the substrate 11, and the other signal end E2 of the electronic component 31 is electrically connected to the ground layer GND. In some embodiments, the electronic component 31 includes at least one signal end E1 and at least one signal end E2 (one or more signal ends E1 or E2). For example, the electronic component 31 as shown in FIG. 1A has one signal end E1 and one signal end E2. The signal ends E1 and E2 can be the leads or pins (electrodes) of the electronic component 31. In some embodiments, the electronic component 31 is, for example, a surface mounted device (SMD), but this disclosure is not limited thereto. Herein, by utilizing surface mount technology (SMT), the signal end E1 can be electrically connected to the conductive pattern 112a of the substrate 11, and the signal end E2 can be electrically connected to the ground layer GND. Herein, a conductive element 311 can be provided between the signal end E1 and the conductive pattern 112a, or/and another conductive element 311 can be provided between the signal end E2 and the ground layer GND. The material of the conductive element 311 includes, for example, tin, gold, copper or silver, aluminum, iron, nickel, cobalt or an alloy or eutectic compound of any of the above materials, or any of other conductive metal materials, and this disclosure is not limited thereto. In some embodiments, the signal ends E1 and E2 of the electronic component 31 can be eutectic connected to the conductive pattern 112a of the substrate 11 by high-temperature thermal fusion (i.e., laser ablation), and the materials thereof can refer to the above embodiments. In some embodiments, the electronic component 31 can be an RFIC (radio-frequency integrated circuit) such as a silicon RFIC or non-silicon RFIC (i.e., GaAs MMIC). In some embodiments, the electronic component 31 can be a photoelectric component, which is a millimeter or micrometer photoelectric chip or photoelectric package. In some embodiment, each photoelectric component can be, for example but not limited to, at least one photoelectric chip, Mini photoelectric chip, Micro photoelectric chip, Micro sensor chip, or at least one package, or a photoelectric chip or package with an unlimited size such as in millimeters, micrometers or smaller.

In this embodiment, the substrate structure 1 can be an AM (Active Matrix) substrate structure, so that the electronic device 3 further includes a plurality of driving elements 32. Each driving element 32 is corresponding to and electrically connected to one corresponding electronic component 31. The driving element 32 can be, for example, a thin-film transistor (TFT), a driving chip, or a driving chiplet for driving the corresponding electronic component 31.

As mentioned above, based on the above design, when each electronic component 31 of the electronic device transmits the high-frequency signal via the conductive structure 12, compared to the conventional structure having non-smooth conductive film or/and hole wall due to the process of utilizing the chemical plating or electroplating to form the conductive film, the surface roughness of the small-diameter segment 122 of each conductive structure 12 is less than the surface roughness of the hole wall W of the corresponding through hole H, so that the signal intensity of the high-frequency signals can be remained after passing through the conductive structure 12 (or even the through hole H in after-mentioned embodiment), thereby improving the signal attenuation of high-frequency signals.

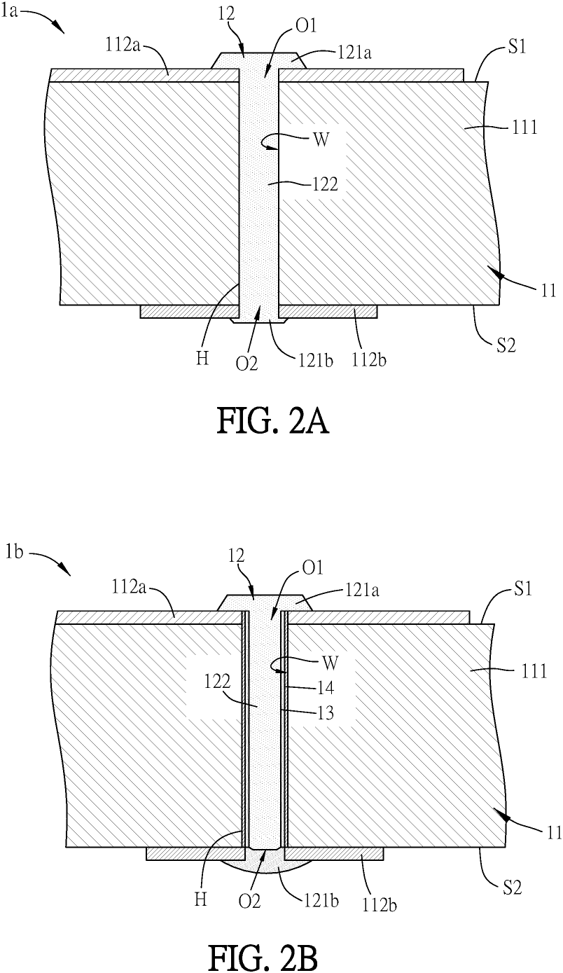

Please refer to FIGS. 2A to 2C individually, wherein FIGS. 2A to 2C are schematic enlarged views of a part of different substrate structures of this disclosure. The substrate structures 1a to 1c as shown in FIGS. 2A to 2C can be applied to the above-mentioned electronic device 3.

Unlike the embodiment of FIG. 1B, in the substrate structure 1a of FIG. 2A, the large-diameter caps 121a and 121b and the small-diameter segment 122 are made of the same material as integrity so as to form a conductive pin. For further comprehension, the large-diameter caps 121a and 121b can be bonded with the conductive patterns 112a, 112b respectively by laser welding, but not limited thereto.

In addition, unlike the embodiment of FIG. 1B, the substrate structure 1b of FIG. 2B further includes a conductive circle 14 encompassing along the hole wall W of the corresponding through hole H and an insulation sleeve 13 sheathing the small-diameter segment 122; and the insulation sleeve 13 is arranged between the small-diameter segment 122 of the corresponding conductive structure 12 and the conductive circle 14 attached onto the hole wall W of the corresponding through hole H. In some embodiments, the length of the insulation sleeve 13 can be less than or equal to the length of the conductive structure 12, and the insulation sleeve 13 can be formed by glass powder. In some cases, the insulation sleeve 13 can be formed by the silicon materials, or compounds with silicon, such silicon oxide, silicon dioxide, silicon nitride, or the like. In some cases, the insulation sleeve 13 can be formed by polymer materials, such as polyimide or materials the like. In some cases, the insulation sleeve 13 can be formed as a whole piece with integrity and stuffed into the corresponding through hole H. In some cases, the insulation sleeve 13 can be formed onto the conductive circle 14 in an attachment or adherence way or any other manner. The conductive circle 14 can be a conductive film formed by electroplating on the surface of the hole wall W. The conductive circle 14 is not limited to full cover the surface of the hole wall W. The insulation sleeve 13, to be noted, keeps the small-diameter segment 122 (the conductive structure 12) insulated from the conductive circle 14. In the high-frequency range, the surface of the conductive structure 12 performs well with reduced transmission loss, in comparison with the transmission loss travelling through the conductive circle 14 along the surface of the hole wall W. In other words, the high-frequency transmission through the surface of the conductive structure 12 has a low loss rather than through the conductive circle 14 along the surface of the hole wall W.

Unlike the embodiment of FIG. 2A, in the substrate structure 1c of FIG. 2C, the large-diameter caps 121a and 121b are made of and existed after process of laser welding, but not limited thereto.

The above-mentioned insulation sleeve and conductive circle can be both applied to the substrate structure described in FIG. 2C.

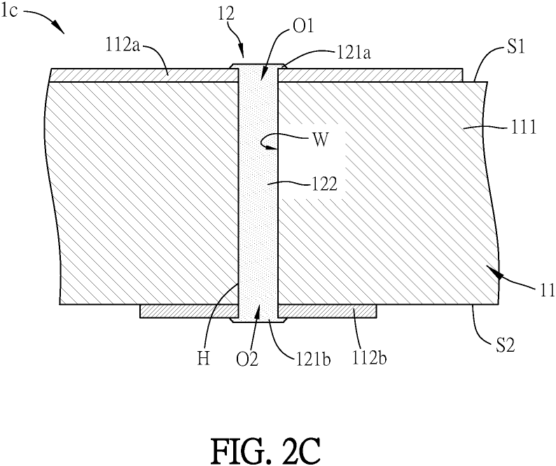

Referring to FIG. 3, this disclosure also provides a method for fabricating a substrate structure 1 as shown in FIG. 2B, which includes the following steps S01 to S03.

The step S01 is to prepare a substrate 11, wherein the substrate 11 includes a substrate body 111, a plurality of through holes H penetrating through the substrate body 111, and two conductive patterns 112a and 112b formed on two opposite surfaces S1 and S2 of the substrate body 111, respectively. The substrate body 111 is defined with two openings O1 and O2 and a hole wall W corresponding to each through hole H.

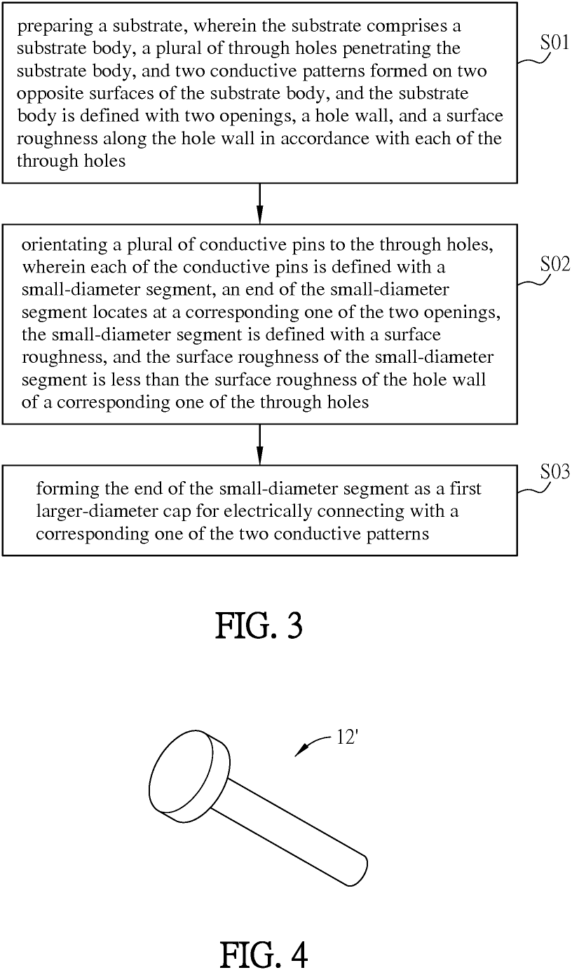

The step S02 is to prepare a plurality of conductive pins 12′ (as shown in FIG. 4) and to orientate the conductive pins 12′ to the through holes H of the substrate 11. Wherein, each of the conductive pins 12′ is defined with a larger-diameter cap 121a (also the first larger-diameter cap 121a) and a small-diameter segment 122 linking to the first larger-diameter cap 121a. The first larger-diameter cap 121a of each conductive pin 12′ locates at the opening O1 of the corresponding through hole H, the small-diameter segment 122 of each conductive pin 12′ locates in the corresponding through hole H, and the surface roughness of the small-diameter segment 122 is less than the surface roughness of the hole wall W of the corresponding through hole H. To be noted, the conductive pins 12′ and through holes H of the substrate 11 are arranged in a one-on-one manner.

The step S03 is to electrically connect the first larger-diameter cap 121a with the conductive pattern 112a. In this step S03, the first larger-diameter cap 121a is electrically connected with the conductive pattern 112a by laser welding.

In some embodiments, the method for fabricating the substrate structure further includes a step of: laser fusing one end of the small-diameter segment 122 away from the first larger-diameter cap 121a so as to form a larger-diameter cap 121b (also a second larger-diameter cap), wherein the second larger-diameter cap 121b is electrically connected to the conductive pattern 112b.

In some embodiments, the method for fabricating the substrate structure further includes a step of: placing a conductive material at one end of the small-diameter segment 122 away from the first larger-diameter cap 121a, and heating the conductive material to form a second larger-diameter cap 121b, wherein the second larger-diameter cap 121b electrically connects the small-diameter segment 122 to the conductive pattern 112b. Herein, the conductive material can be, for example but not limited to, a metal material such as gold, silver, copper, aluminum, iron, nickel, cobalt or tin.

In some embodiments of the method for fabricating the substrate structure, the step S02 provides conductive pins locates in the corresponding through holes H, each of the conductive pins is defined with a small-diameter segment 122 only. An end of each conductive pin (small-diameter segment 122) locates at the opening O1 of the corresponding through hole H, and the surface roughness of the small-diameter segment 122 is less than the surface roughness of the hole wall W of the corresponding through hole H. The step S03 is to form the end of each conductive pin (small-diameter segment 122) as the first larger-diameter cap 121a with the conductive pattern 112a by laser welding, which is not limited thereto. For further comprehension, the second larger-diameter cap 121b is formed by welding or soldering processes.

In some embodiments, the method for fabricating the substrate structure further includes a step before the step S02, the step includes, forming a conductive circle encompassing along the hole wall of the corresponding through hole, and applying one or more insulation sleeves disposed in the corresponding through holes. To be noted, the conductive pins and through holes of the substrate are arranged in a one-on-one manner. The insulation sleeves keep the conductive structures insulated from the conductive circle.

It should be understood that additional operations can be provided before, during, and after the method, and some of the operations described can be replaced or eliminated for other embodiments of the method.

From the foregoing, it will be appreciated that various embodiments in accordance with the present disclosure have been described herein for purposes of illustration, and that various modifications may be made without departing from the scope and spirit of the present teachings. Accordingly, the various embodiments disclosed herein are not intended to be limiting of the true scope and spirit of the present teachings.

While the disclosure has been described by way of example and in terms of embodiment, it should be understood that the disclosure is not limited thereto. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A substrate structure, comprising:
a substrate having a substrate body, a plural of through holes, and two conductive patterns, wherein the substrate body is defined with two surfaces opposite to each other, the through holes penetrates the substrate body, and two conductive patterns, and the two conductive patterns are formed on the two surfaces of the substrate body respectively, wherein the substrate body, in accordance with each of the through holes, is defined with two openings, a hole wall, and a surface roughness along the hole wall; and
a plural of conductive structures respectively oriented at the through holes; wherein each of the conductive structures is defined with two larger-diameter caps, and a small-diameter segment linking the two larger-diameter caps, in each of the conductive structures, the two larger-diameter caps are respectively located at the two openings and electrically connected the two conductive patterns, the small-diameter segment is defined with a surface roughness, the surface roughness of the small-diameter segment is less than the surface roughness of the hole wall of a corresponding one of the through holes.

2. The substrate structure of claim 1, wherein the substrate is a resilient board.

3. The substrate structure of claim 1, wherein the substrate is a rigid board.

4. The substrate structure of claim 1, wherein the substrate includes a rigid board, a resilient board, and an adhesion layer connecting the rigid board and the resilient board.

5. The substrate structure of claim 4, wherein the resilient board and the adhesion layer further define a combined thickness less than or equal to 60 µm.

6. The substrate structure of claim 1, wherein in each of the conductive structures, one of the two larger-diameter caps and the small-diameter segment are formed to be a conductive pin as integrity.

7. The substrate structure of claim 1, wherein the small-diameter segment comprises metallic materials including gold, silver, tin, copper, aluminum, iron, nickel, or cobalt, or an alloy including at least one of the foresaid metallic materials.

8. The substrate structure of claim 1, wherein a part of the small-diameter segment directly contacts the hole wall.

9. The substrate structure of claim 1, wherein the substrate body is defined with a thickness, and the thickness is less than or equal to 1.1 mm.

10. The substrate structure of claim 1, wherein the substrate body is defined with a thickness, and the thickness is greater than or equal to 0.01 mm.

11. The substrate structure of claim 1, wherein each of the through holes is defined with a diameter, and the diameter of the through hole is less than or equal to 100 µm.

12. The substrate structure of claim 1, wherein each of the through holes is defined with a diameter, and the diameter of the through hole is less than or equal to 80 µm.

13. The substrate structure of claim 1, wherein each of the through holes is defined with a diameter, and the diameter of the through hole is greater than or equal to 35 µm.

14. The substrate structure of claim 1, wherein the small-diameter segment of the each of the conductive structures is defined with a diameter, and the diameter of the small-diameter segment is less than or equal to 50 µm.

15. The substrate structure of claim 1, wherein each of the through holes is defined with a depth-to-diameter aspect ratio, and the depth-to-diameter aspect ratio is less than or equal to 50.

16. The substrate structure of claim 1, wherein one of the larger-diameter caps of one of the conductive structures is defined with a diameter, and the diameter of the larger-diameter cap is greater than a corresponding one of the openings of the through holes.

17. The substrate structure of claim 1, wherein the substrate structure further comprises a conductive circle encompassing along the hole wall of a corresponding one of the through holes; and an insulation sleeve sheathing the small-diameter segment and arranged between the small-diameter segment of the corresponding conductive structure and the hole wall of a corresponding one of the through holes.

18. The substrate structure of claim 1, wherein one of the conductive patterns comprises a conductive pad, and a corresponding one of the conductive structures electrically connects the conductive pads.

19. An electronic device, comprising the substrate structure of claim 1 and a plural of electrical components distributed on one of the surfaces of the substrate body, electrically connected one of the conductive patterns in a respective manner to the other one of the conductive patterns through the conductive structures.
